(19) United States
(12) Patent Application Publication
(10) Pub. No.: US 2006/0220158 A1
(43) Pub. Date: Oct. 5, 2006

(54) Semiconductor device and manufacturing method thereof

(75) Inventor: Teruo Takizawa, Nagano-Ken (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/393,073

(22) Filed: Mar. 29, 2006

(30) Foreign Application Priority Data
Mar. 30, 2005 (JP) 2005-097981

(51) Int. Cl. H01L 29/94

(52) U.S. Cl. 257/412; 257/413; 257/E27.05

(57) ABSTRACT

A semiconductor device includes: a semiconductor layer; a high dielectric constant gate insulation film disposed above the semiconductor layer, the high dielectric constant gate insulation film containing a plurality of elements; a gate electrode disposed on the high dielectric constant gate insulation film; and an impurity region disposed in the semiconductor layer and serving as one of a source region and a drain region, wherein the gate electrode includes a first gate electrode layer made of a material hardly bonded to at least one of the elements included in the high dielectric constant gate insulation film.

### BACKGROUND

1. Technical Field

The present invention relates to a semiconductor device and a manufacturing method thereof.

2. Related Art

The gate insulation film of MIS transistors has become thinner in line with the recent miniaturization of semiconductor devices. The silicon oxide film, which is a typical material of the gate insulation film, however, does not function as the insulation film since currents pass through the film by a quantum tunnel effect when it is formed too thin. Therefore, a technique has been developed in which a high dielectric constant material (high-k material) is employed for the gate insulation film as the material that can reduce its film thickness to an electrical equivalent thickness thinner than the physical thickness, even though which is rather thick, due to the high dielectric constant. As the material having a high dielectric constant, oxides including-such as hafnium, aluminum are exemplified.

IEEE Electron Device Letters, Vol. 25, No. 6, June 2004, p. 408-p. 410 is an example of related art.

However, in resent researches, a problem is reported in which the threshold voltage of MIS transistors cannot be controlled due to a pinned Fermi level when the gate electrode made of polysilicon is formed on the gate insulation film made of the high dielectric constant material. For example, the problem is reported in the example of the related art. Accordingly, a MIS transistor having the gate insulation film made of the high dielectric constant material and good controllability of the threshold voltage is expected to be developed.

### SUMMARY

An advantage of the invention is to provide a semiconductor device, which is a MIS transistor having a gate insulation film made of a high dielectric constant material, has good controllability of threshold voltage, and a manufacturing method thereof.

(1) A semiconductor device according to a first aspect of the invention includes: a semiconductor layer; a high dielectric constant gate insulation film, which contains a plurality of elements, disposed above the semiconductor layer; a gate electrode disposed on the high dielectric constant gate insulation film; and an impurity region disposed in the semiconductor layer and serving as one of a source region and a drain region. The gate electrode includes a first gate electrode layer made of a material hardly bonded to at least one of the elements included in the high dielectric constant gate insulation film.

According to the semiconductor device of the first aspect of the invention, a semiconductor device having good controllability on threshold voltage can be provided. In a semiconductor device of related art, in which a gate electrode made of polysilicon is disposed on a high dielectric constant gate insulation film, an element included in the high dielectric constant gate insulation film is bonded to silicon at the interface between the high dielectric constant gate insulation film and polysilicon layer. This is considered as a factor of the pinning phenomenon of the Fermi level as described in the example of related art. However, in the first aspect of the invention, a material that does not cause the phenomenon is used as the gate electrode depending on the material of the high dielectric constant gate insulation film. As a result, a semiconductor device can be provided in which the Fermi level is suppressed from being fixed, and has good controllability on threshold voltage.

Here, the high dielectric constant gate insulation film in the first aspect of the invention is defined as the gate insulation film made of a material having a dielectric constant smaller than that of SiO₂ (i.e. 3.8). In addition, in following aspects as well as the first aspect of the invention, a specific layer A (hereinafter, referred to as layer A) is formed above another specific layer B (hereinafter, referred to as layer B) includes the following cases. One is a case in which the layer B is directly formed on the layer A. The other is a case in which the layer B is formed on the layer A with another layer therebetween.

(2) A semiconductor device according to a second aspect of the invention includes: a semiconductor layer, a high dielectric constant gate insulation film disposed above the semiconductor layer; a gate electrode disposed on the high dielectric constant gate insulation film; and an impurity region disposed in the semiconductor layer and serving as one of a source region and a drain region. The high dielectric constant gate insulation layer is an oxide film containing oxygen atoms. The gate electrode includes a first gate electrode layer made of a material hardly oxidized by the oxygen atoms included in the high dielectric constant gate insulation film.

According to the semiconductor device of the second aspect of the invention, a semiconductor device having good controllability on threshold voltage can be provided. In a semiconductor device of related art, in which a gate electrode made of polysilicon is disposed on a high dielectric constant gate insulation film that is an oxide film, oxygen atoms included in the high dielectric constant gate insulation film is bonded to silicon. This is considered as a factor of adversely affecting the controllability on threshold voltage as described in the example of related art. However, according to the second aspect of the invention, the gate electrode is formed by a material hardly oxidized by the oxygen atoms included in the high dielectric constant gate insulation film even in a case where the high dielectric constant gate insulation film made of an oxide is used. As a result, a semiconductor device can be provided in which the Fermi level is suppressed from being fixed, and has good controllability on threshold voltage.

(3) In the semiconductor device, the first gate electrode layer can include at least one of elements hardly bonded to oxygen atoms as compared with silicon.

In this case, since at least one of elements hardly bonded to oxygen atoms as compared with silicon is included in the first gate electrode layer, oxygen atoms are stably present in the high dielectric constant gate insulation film without losing them from the film. Accordingly, no dipole moment caused by the oxygen atoms loss occurs between the high dielectric constant gate insulation film and first gate electrode layer, allowing the pinning phenomenon at the Fermi level to be suppressed.

The semiconductor device can further include the following cases.

(4) In the semiconductor device, the first gate electrode layer can be in laminar contact with the upper surface of the high dielectric constant gate insulation film.

(5) In the semiconductor device, the first gate electrode layer can be one of a germanium layer and a silicon germanium layer.

Generally, it is considered that the bonding between germanium and oxygen atoms is unstable as compared with that of silicon and oxygen atoms. That is, germanium and oxygen atoms are hardly bonded as compared with the bonding between silicon and oxygen atoms. In this case, since the first gate electrode layer is a germanium layer or a silicon germanium layer both of which are weakly bonded to oxygen atoms, a phenomenon can be suppressed in which oxygen atoms included in the high dielectric constant gate insulation film is bonded to the gate electrode material. Here, in this case, the germanium layer and silicon germanium layer can be in any crystalline state of single crystalline, polycrystalline, and amorphous.

(6) In the semiconductor device, the germanium layer or silicon germanium layer can be P-type.

In this case, the work function of the gate electrode can be nearly the same as the intrinsic mid gap energy of silicon. As a result, the quantity of impurities implanted into a channel can be lowered.

(7) In the semiconductor device, the high dielectric constant gate insulation film can be at least any one of a hafnium oxide film, an aluminum oxide film, and a hafnium aluminate based film, or a multilayered film composed of a combination of the hafnium oxide film, the aluminum oxide film, and the hafnium aluminate based film.

(8) In the semiconductor device, the high dielectric constant gate insulation film can be directly formed on the silicon oxide film formed on the uppermost surface of the semiconductor layer.

(9) In the semiconductor device, the uppermost layer of the gate electrode can be a silicide metal layer.

(10) In the semiconductor device, the gate electrode at least can be structured so that the second gate electrode layer is deposited on the first gate electrode layer.

In this case, the silicide layer can be well formed since the uppermost layer of the gate electrode is the second gate electrode layer, for example, made of a material containing no germanium, such as a polysilicon layer. As a result, a semiconductor device can be provided that includes a gate electrode having a low resistance.

(11) In the semiconductor device, the second gate electrode layer can be a polysilicon layer.

(12) In the semiconductor device, the semiconductor layer can be formed on an insulator.

In this case, a semiconductor device can be provided that has a so-called SOI structure. As a result, a semiconductor device can be provided that has low power consumption and low driving voltage.

(13) A method for manufacturing a semiconductor device according to a third aspect of the invention includes: preparing a semiconductor layer; forming a high dielectric constant gate insulation film, which contains a plurality of elements, above the semiconductor layer; forming a gate electrode on the high dielectric constant gate insulation film; and implanting an impurity into the semiconductor layer so as to form an impurity region serving as one of a source region and a drain region. Forming the gate electrode includes forming a first gate electrode layer made of a material hardly bonded to at least one of the elements included in the high dielectric constant gate insulation film.

According to the method for manufacturing a semiconductor device of the third aspect of the invention, a semiconductor device can be manufactured in which controllability on threshold voltage is improved.

(14) In the method for manufacturing a semiconductor device, forming the high dielectric constant gate insulation film can include forming an oxide film, while forming the gate electrode can include forming a first gate electrode layer made of a material hardly oxidized by oxygen atoms included in the high dielectric constant gate insulation film.

### BRIEF DESCRIPTION OF THE DRAWINGS

The invention will be described with reference to the accompanying drawings, wherein like numbers refer to like elements, and wherein:

FIG. 1 is a cross-sectional view schematically illustrating a first semiconductor device according to a first embodiment of the invention.

FIG. 2 is a cross-sectional view schematically illustrating a second semiconductor device according to a second embodiment of the invention.

FIG. 3 is a cross-sectional view schematically illustrating a method for manufacturing the second semiconductor device according to a third embodiment of the invention.

FIG. 4 is a cross-sectional view schematically illustrating the method for manufacturing the second semiconductor device according to the third embodiment of the invention.

FIG. 5 is a cross-sectional view schematically illustrating the method for manufacturing the second semiconductor device according to the third embodiment of the invention.

### DESCRIPTION OF EXEMPLARY EMBODIMENTS

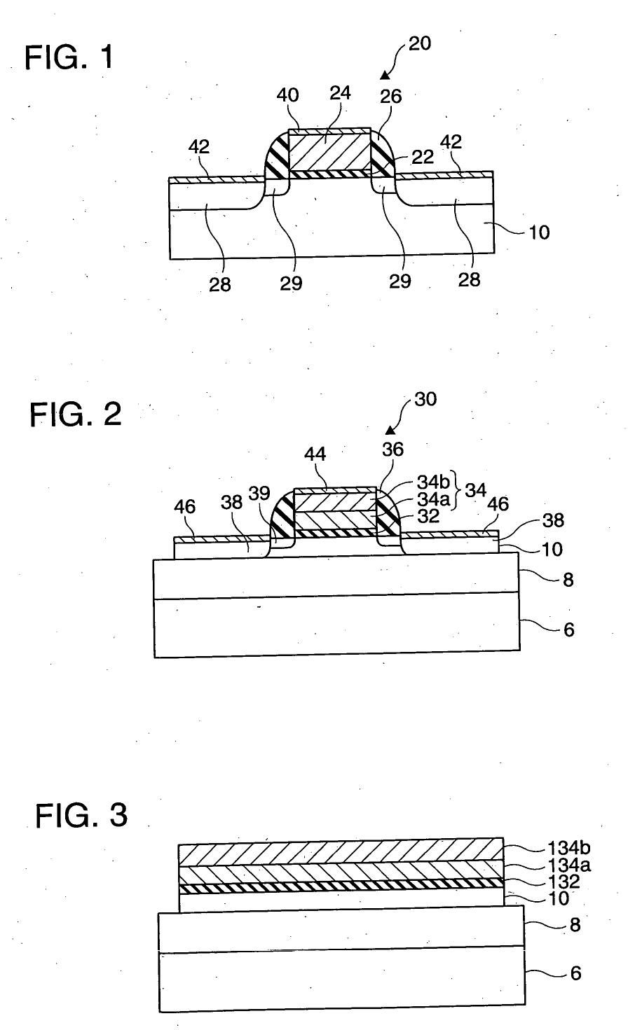

Embodiments according to the invention will be described below with reference to the accompanying drawings. FIG. 1 is a cross-sectional view schematically illustrating a first semiconductor device according to a first embodiment of the invention. FIG. 2 is a cross-sectional view schematically illustrating a second semiconductor device according to a second embodiment of the invention. First, the first semiconductor device will be described. Then, the second semiconductor device will be described.

As shown in FIG. 1, a MIS transistor 20 is provided to a semiconductor layer 10, which is a bulk semiconductor material, in the first semiconductor device of the first embodiment. The MIS transistor 20 includes a high dielectric constant gate insulation layer 22 (hereinafter, may be referred to as a gate insulation film 22), a gate electrode 24 provided on the gate insulation film 22, a sidewall 26 provided to the side face of the gate electrode 24, and an impurity region 28 provided in the semiconductor layer 10 so as to be a source region or a drain region. In addition, an LDD region 29 is provided in the semiconductor layer 10 under the sidewall 26. The LDD region 29 is an impurity region having a lower concentration than that of the impurity region 28. Further, silicide layers 40 and 42 are respectively provided on the uppermost surfaces of the gate electrode 24 and the impurity region 28.

The gate insulation film 22 is made of a material having a higher dielectric constant than that of the silicon oxide film. Specifically, TiO₂, Ta₂O₅, HfO₂, HfAlOx, HfAlONx, ZrO₂, La₂O₃, Y₂O₃, and Al₂O₃ are exemplified as the material. In addition, the high dielectric constant gate insulation film may be formed on a thin silicon oxide film directly formed on the semiconductor layer 10 since transistor characteristics may be influenced when an interface state is present at the interface between the semiconductor layer 10 and the gate insulation film 22. For example, even in a case where a silicon oxide film having a thickness of 1 nm is directly formed on the semiconductor layer 10 and a high dielectric constant insulation film having a dielectric constant k=20 is deposited at a thickness of 1 nm on the silicon oxide film, the thickness is only 1.2 nm in terms of silicon oxide film. As a result, a leak current, which is directly induced by the tunnel phenomenon if only the silicon oxide film is formed, can be reduced by using the high dielectric constant gate insulation film.

The gate electrode 24 is made of a material hardly bonded to at least one of the elements included in the gate insulation film 22. Here, the material hardly bonded to the element included in the gate insulation film 22 is the material that has a weak bonding property to oxygen atoms as compared with the bonding property (tendency to easily be bonded) of silicon and oxygen atoms when the gate insulation film 22 is an oxide film containing oxygen atoms at a desired ratio. Put simply, the material is hardly oxidized than a silicon atom. As the material, a layer including germanium is exemplified. Specifically, the layer includes a germanium layer and a silicon germanium layer. The crystalline state of the germanium and silicon germanium layers may be any of single crystalline, polycrystalline, and amorphous. Here, FIG. 1 shows a case where a single germanium layer serves as the gate electrode 24. Thus, a first gate electrode layer corresponds to the gate electrode 24.

In addition, a P-type germanium layer or a silicon germanium layer may be used as the gate electrode 24. Particularly, the P-type germanium layer can reduce the impurity concentration in a channel since it has a work function close to the intrinsic mid gap energy of silicon. Accordingly, it has an advantage in that the deterioration of carrier mobility in a channel can be suppressed.

The sidewall 26 can be formed with a known material. For example, an oxide film (silicon oxide film), a nitride film (silicon nitride film), or a mulitilayered film of them can be used for the sidewall 26.

The silicide layers 40 and 42, for example, can be achieved by silicidizing cobalt, titanium, vanadium, chromium, manganese, iron, nickel, zirconium, niobium, molybdenum, ruthenium, hafnium, tantalum, tungsten, iridium, or platinum, or an alloy layer composed of them. The silicide layers 40 and 42 respectively allow the gate electrode 24 and impurity region 28 to be low resistance.

Next, the second semiconductor device of the second embodiment will be described with reference to FIG. 2. In the description on the second semiconductor device, the detailed description on the structure common to the first semiconductor will be omitted.

As shown in FIG. 2, in the second semiconductor device of the second embodiment, an insulation layer 8 and the semiconductor layer 10 are sequentially formed on a supporting base 6. A MIS transistor 30 is provided on the semiconductor layer 10. The MIS transistor has the same structure of the MIS transistor 20 of the first embodiment. Specifically, the MIS transistor 30 includes a gate insulation film 32 on the semiconductor layer 10, a gate electrode 34 provided on the gate insulation film 32, a sidewall provided to the side face of the gate electrode 34, and an impurity region 38 provided in the semiconductor layer 10 and serves as a source region or drain region. Further, silicide layers 44 and 46 are respectively provided on the uppermost surfaces of the gate electrode 34 and the impurity region 28.

The gate insulation film 32, sidewall 36 and silicide layers 44 and 46 can be the same structure of the gate insulation film 22, sidewall 26, and silicide layers 40 and 42 of the first semiconductor device respectively. In the second semiconductor device, the gate electrode 34 is particularly differs from that in the first semiconductor device. The gate electrode 34 will be minutely described below.

The gate electrode 34 is composed of deposited multiple layers. Specifically, the gate electrode 34 is provided so as to come in contact with the gate insulation film 32. That is, the gate electrode 34 is composed of a first gate electrode layer 34a directly provided on the gate insulation film 32, and a second gate electrode layer 34b provided on the first gate electrode layer 34a. The first gate electrode layer 34a is made of a material hardly bonded to at least one of the elements included in the gate insulation film 32. Specifically, it is the same material of the gate electrode 24. The second gate electrode layer 34b is preferably made of a layer containing no germanium, such as polysilicon. While a case where two gate electrode layers are deposited is shown in FIG. 2, but not limited to this, as long as the first gate electrode layer 34a is in laminar contact with the gate insulation film 34, remaining layer of the gate electrode layer may be deposited with more than two layers.

A method for manufacturing a semiconductor device according to a third embodiment of the invention will be explained with reference to FIGS. 3 through 5. FIGS. 3 through 5 are cross-sectional views schematically illustrating processes of a method for manufacturing the second semiconductor device (refer to FIG. 2) of the second embodiment of the invention.

First, as shown in FIG. 3, an SOI substrate is prepared in which the insulation layer 8 and semiconductor layer 10 are sequentially deposited on the supporting base 6. The SOI substrate is not limited to the example that will be described hereinafter in which the insulation layer 8 and semiconductor layer 10 are sequentially deposited on the supporting base 6, but a separation-by-implanted-oxygen (SIMOX) substrate, a bonded substrate, a laser annealed substrate, or the like can be used. As the semiconductor layer 10, for example, Si, Si—Ge, GaAs, InP, GaP, GaN, or the like can be used. Then a region for forming an element is partitioned. The region for forming an element can be partitioned by a known isolation method such as a local oxidation of silicon (LOCOS) method, a shallow trench isolation method, and a mesa-type isolation method. In the third embodiment, the semiconductor layer 10 is partitioned by the mesa-type isolation method as the region for forming an element.

Next, an insulation layer 132 is formed, which will be patterned so as to be the gate insulation film 32 (refer to FIG. 2) in a subsequent process. The insulation layer 132 is formed with a high dielectric constant material. Specifically, the insulation film exemplified as above is formed. The insulation layer 132 can be formed by a known forming method such as an atmospheric CVD method, a reduced pressure CVD method, an atomic layer deposition (ALD) method with each material.

In addition, silicon oxide film may be formed on the interface between the semiconductor layer 10 and gate insulation film 32 with an extremely thin thickness before forming the insulation layer 132. The resulting film allows the interface state between the semiconductor layer 10 and gate insulation film 32 to be drastically improved, and plays an important role to achieve good transistor characteristics. For example, a thin silicon oxide film having a thickness of about 1 nm (not shown) is formed on the SOI substrate, and then a HfAlONx fim having a thickness of about 1 nm can be formed by the ALD method.

Then, a first electrode layer 134a, which will serve as the first gate electrode layer 34a, is formed on the insulation layer 132. Accordingly, the first gate electrode layer 34a (first electrode layer 134a) comes in contact with the gate insulation film 32. Next, a second electrode layer 134b, which will serve as the second electrode layer 34b, is formed on the first electrode layer 134a. The first electrode layer 134a and second electrode layer 134b can be formed with the materials exemplified above. The first electrode layer 134a and second electrode layer 134b can be formed by, for example, the CVD method. In a case where the p-type germanium layer is formed as the first electrode layer 134a, the following methods are available: a method in which a p-type impurity such as boron is ion implanted after forming a germanium layer; and a method in which a germanium layer is formed by the CVD method by using forming gas containing such as B₂H₆ as a supply source of the P-type impurity.

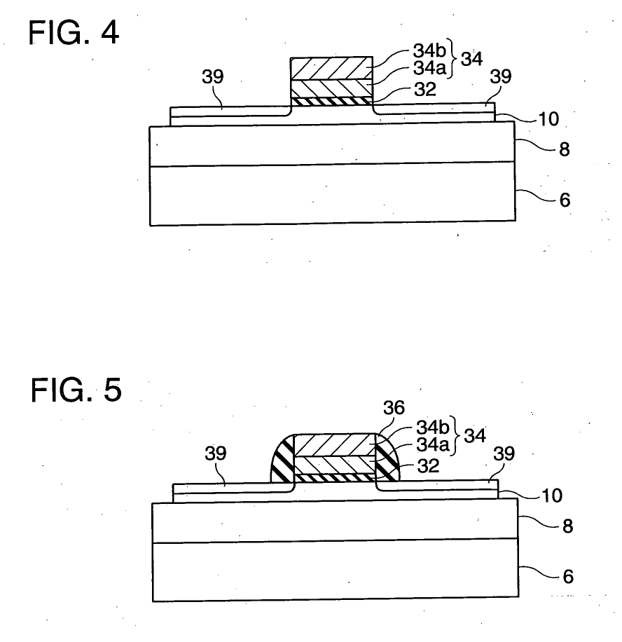

Then, a mask layer (not shown) is formed on the second electrode layer 134b in a predetermined pattern. Subsequently, as shown in FIG. 4, the gate electrode 34 in which the first gate electrode layer 34a and second electrode layer 34b are deposited, and the gate insulation film 32 are formed by etching using a known etching technique with the mask layer.

Next, a predetermined conductive impurity is implanted into the semiconductor layer 10 so as to form an LDD region 39. The impurity can be implanted by using a known ion implantation method.

Then, as shown in FIG. 5, the sidewall 36 is formed to the side face of the gate electrode 34. An insulation layer (not shown) is formed on the entire surface of the semiconductor layer 10 so as to cover the gate electrode 34. By performing an isotropic etching to the insulation layer, the sidewall 36 is formed. Subsequently, as shown in FIG. 2, the impurity region 38 is formed by implanting an impurity into the semiconductor layer 10. The impurity is implanted by a known ion implantation method, and heat treatment is carried out for diffusing the impurity if necessary.

Next, as referred to FIG. 2, the silicide layers 44 and 46 are respectively formed on the uppermost surfaces of the gate electrode 34 and impurity region 38. The silicide layers 44 and 46 are formed as follows: a metal layer is formed above the entire surface of the semiconductor layer 10 for silicidization; the metal layer is subjected to, for example, heat treatment so that silicidization reaction occurs; and then the unreacted metal layer is removed so as to form the silicide layers 44 and 46. As the metal layer, materials exemplified for the silicide layers 40 and 42 of the first semiconductor device can be used. In forming the silicide layers, the formation of the gate electrode 34 having a multilayered structure shown in the embodiment shows the following advantage. Generally, a layer including germanium, which is used for such as the first gate electrode layer 34a, has a difficulty to form a silicide layer having a low resistance since the silicidization reaction cannot be well promoted. In contrast, in the second semiconductor device of the second embodiment, the silicide layer is formed by silicidizing the second gate electrode layer 34b made of polysilicon. Therefore, a silicide layer having a low resistance can be formed by performing the silicidization reaction well without the problem described above.

The second semiconductor device of the second embodiment can be manufactured by the above-described processes.

The advantages of the first and second semiconductor devices of the embodiments will be described below.

According to the first and second semiconductor devices of the embodiments, a semiconductor device including the MIS transistor 20 or 30 each of which has good controllability on threshold voltage can be provided. Because, the bonding of silicon and oxygen atoms in each of the high dielectric constant gate insulation films 22 and 23, which is considered as an factor of the pinning phenomena at Fermi level, is suppressed by disposing one layer containing silicon lower than others in each of the gate electrodes 24 and 34 so as to come contact with respective gate insulation films 22 and 32. Accordingly, the Fermi level can be suppressed from being fixed. As a result, a semiconductor device can be provided that is miniaturized and has good controllability on threshold voltage.

In addition, the semiconductor devices of the embodiments have the following advantage by applying the P-type germanium layer to the first gate electrodes 24 and 34a. The P-type germanium layer can improve further the controllability on threshold voltage. Because the P-type germanium layer has a work function close to the intrinsic mid gap energy of silicon, allowing the increase of the absolute value of the Fermi band voltage to be suppressed, and in which the Fermi level is suppressed from being fixed as described above.

Further, in a CMOS composed of the MIS transistor of the embodiment, the on-current value of N channel type transistor and P channel type transistor depends on the theoretical effective carrier mobility. As a result, a CMOS having well-balanced CMOS characteristics can be provided.

The invention is not limited to the above-described embodiments. Various changes can be made. For example, the invention includes structures that are substantively the same as those of described in the embodiments (for example, structures including the same functions, methods, and results or structures including the same aims and results). Also, the invention includes structures that nonessential parts of the structures described in the embodiments are replaced. In addition, the invention includes structures achieving the same effects or aims as those of the structures described in the embodiments. Further, the invention includes structures in which related arts are added to the structures described in the embodiments.

The entire disclosure of Japanese Patent Application No. 2005-097981, filed Mar. 30, 2005 is expressly incorporated by reference herein.

What is claimed is:

1. A semiconductor device, comprising:
a semiconductor layer;
a high dielectric constant gate insulation film disposed above the semiconductor layer, the high dielectric constant gate insulation film containing a plurality of elements;
a gate electrode disposed on the high dielectric constant gate insulation film; and
an impurity region disposed in the semiconductor layer and serving as one of a source region and a drain region, wherein the gate electrode includes a first gate electrode layer made of a material hardly bonded to at least one of the elements included in the high dielectric constant gate insulation film.

2. A semiconductor device, comprising:
a semiconductor layer;
a high dielectric constant gate insulation film disposed above the semiconductor layer;
a gate electrode disposed on the high dielectric constant gate insulation film; and
an impurity region disposed in the semiconductor layer and serving as one of a source region and a drain region, wherein the high dielectric constant gate insulation layer is an oxide film containing an oxygen atom, and the gate electrode includes a first gate electrode layer made of a material hardly oxidized by the oxygen atom included in the high dielectric constant gate insulation film.

3. The semiconductor device according to claim 2, the first gate electrode layer including at least one of elements hardly bonded to an oxygen atom as compared with silicon.

4. The semiconductor device according to claim 1, wherein the first gate electrode layer is in laminar contact with an upper surface of the high dielectric constant gate insulation film.

5. The semiconductor device according to claim 1, wherein the first gate electrode layer is one of a germanium layer and a silicon germanium layer.

6. The semiconductor device according to claim 5, wherein one of the germanium layer and the silicon germanium layer is P-type.

7. The semiconductor device according to claim 1, wherein the high dielectric constant gate insulation film is one of at least any one of a hafnium oxide film, an aluminum oxide film, and a hafnium aluminate based film, and a multilayered film composed of a combination of the hafnium oxide film, the aluminum oxide film, and the hafnium aluminate based film.

8. The semiconductor device according to claim 1, wherein the high dielectric constant gate insulation film is directly formed on a silicon oxide film formed on an uppermost surface of the semiconductor layer.

9. The semiconductor device according to claim 1, wherein at least an uppermost layer of the gate electrode is a silicide metal layer.

10. The semiconductor device according to claim 1, wherein the gate electrode is structured so that the second gate electrode layer is deposited on the first gate electrode layer.

11. The semiconductor device according to claim 1, wherein the second gate electrode layer is a polysilicon layer.

12. The semiconductor device according to claim 1, wherein the semiconductor layer is formed on an insulator.

13. A method for manufacturing a semiconductor device, comprising:
preparing a semiconductor layer;
forming a high dielectric constant gate insulation film above the semiconductor layer, the high dielectric constant gate insulation film containing a plurality of elements;
forming a gate electrode on the high dielectric constant gate insulation film; and
implanting an impurity into the semiconductor layer so as to form an film purity region serving as one of a source region and a drain region, wherein forming the gate electrode includes forming a first gate electrode layer made of a material hardly bonded to at least one of the elements included in the high dielectric constant gate insulation film.

14. The method for manufacturing a semiconductor device according to claim 13, wherein forming the high dielectric constant gate insulation film includes forming an oxide film, while forming the gate electrode includes forming a first gate electrode layer made of a material hardly oxidized by an oxygen atom included in the high dielectric constant gate insulation film.
